(19) United States
(12) Patent Application Publication
(10) Pub. No.: US 2026/0015765 A1
(43) Pub. Date: Jan. 15, 2026

(54) METHOD FOR MANUFACTURING EPITAXIAL WAFER

(71) Applicant: SUMCO CORPORATION, Tokyo (JP)

(72) Inventors: Naoyuki WADA, Tokyo (JP); Yu MINAMIDE, Tokyo (JP)

(73) Assignee: SUMCO CORPORATION, Tokyo (JP)

(21) Appl. No.: 19/312,908

(22) Filed: Aug. 28, 2025

Related U.S. Application Data
(63) Continuation of application No. 17/417,650, filed on Jun. 23, 2021.

(30) Foreign Application Priority Data
Dec. 27, 2018 (JP) 2018-244844

(51) Int. Cl. C30B 25/12; C23C 16/24; C23C 16/458; C23C 16/54; C30B 29/06

(52) U.S. Cl. CPC C30B 25/12; C23C 16/4583; C23C 16/54; C23C 16/24; C30B 29/06

(57) ABSTRACT

A method for manufacturing epitaxial wafers includes preparing a vapor deposition device which includes a ring-shaped carrier that supports an outer edge of a wafer, and which uses a plurality of the carriers. The carrier, or the carrier in combination with a susceptor, includes a circumferential structure or shape corresponding to the crystal orientation of the wafer. The method includes mounting a before-treatment wafer on the carrier such that the wafer's circumferential crystal orientation aligns with the carrier or the carrier in combination with the susceptor structure; transporting a plurality of before-treatment wafers from a storage container through a factory interface, load-lock chamber, and wafer transfer chamber to a reaction chamber in that order; and transporting a plurality of after-treatment wafers from the reaction chamber, through the wafer transfer chamber, the load-lock chamber and the factory interface, to the wafer storage container in that order.

### CROSS REFERENCE TO RELATED APPLICATION

The present application is a continuation of U.S. patent application Ser. No. 17/417,650, filed Jun. 23, 2021, which is a U.S. National Phase entry of International Patent Application No. PCT/JP2019/043261, filed Nov. 5, 2019, which claims the benefit of Japanese Patent Application No. 2018-244844, filed Dec. 27, 2018. The disclosures of each of the above-noted documents are expressly incorporated herein by reference in their entirety.

### FIELD OF THE DISCLOSURE

The present invention relates to a method for manufacturing epitaxial wafers using a vapor deposition device and a carrier.

### BACKGROUND OF THE DISCLOSURE

In order to keep damage to a reverse face of a silicon wafer to a minimum in vapor deposition devices used in manufacturing epitaxial wafers, for example, transporting the silicon wafer through steps from a load-lock chamber to a reaction chamber in a state where the silicon wafer is mounted on a ring-shaped carrier has been proposed (Patent Literature 1).

In this type of vapor deposition device, whereas a before-treatment wafer is mounted on a ring-shaped carrier standing by in the load-lock chamber, an after-treatment wafer is transported from the reaction chamber to the load-lock chamber still mounted on a ring-shaped carrier.

### RELATED ART

### Patent Literature

Patent Literature 1: U.S. Patent Application No. 2017/0110352
Patent Literature 2: Japanese Patent Laid-open Publication No. 2007-294942

### SUMMARY OF THE DISCLOSURE

### Problems to Be Solved by the Disclosure

However, in the conventional ring-shaped carrier, abrupt changes in film thickness of the formed epitaxial film at a circumferential edge of a silicon single crystal wafer cannot be inhibited, and there is therefore an issue of difficulty in flattening out the circumferential edge, in particular.

The present invention undertakes to solve the issue of providing a vapor deposition device that can keep damage to a reverse face of a silicon wafer to a minimum while making a uniformly thick CVD film at a circumferential edge of the wafer.

### Means for Solving the Problems

The present invention is a method for manufacturing epitaxial wafers comprising:
preparing a vapor deposition device which is provided with a ring-shaped carrier that supports an outer edge of a wafer, and which uses a plurality of the carriers,
wherein the vapor deposition device comprises a factory interface, a load-lock chamber, a wafer transfer chamber and a reaction chamber,
the load-lock chamber communicates with the factory interface via a first door and also communicates with the wafer transfer chamber via a second door,
the wafer transfer chamber communicates, via a gate valve, with the reaction chamber in which a CVD film is formed on the wafer,
the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber,
the factory interface is provided with a second robot that extracts the before-treatment wafer from a wafer storage container and mounts the wafer on a carrier standing by in the load-lock chamber, and also stores in the wafer storage container an after-treatment wafer mounted on the carrier that has been transported to the load-lock chamber,
the load-lock chamber is provided with a holder that supports the carrier,
the reaction chamber is provided with a susceptor that supports the carrier,
the carrier is formed in an endless ring shape having a bottom surface that rests on a top surface of the susceptor, a top surface touching and supporting an outer edge of a reverse face of the wafer, an outer circumferential wall surface, and an inner circumferential wall surface, and
the carrier, or the carrier and the susceptor, are configured with a structure or shape in a circumferential direction of the top surface that has a correspondence relationship to a crystal orientation in the circumferential direction of the wafer;
mounting the before-treatment wafer on the carrier such that the crystal orientation in the circumferential direction of the before-treatment wafer and the structure or shape of the carrier, or of the carrier and the susceptor, in the circumferential direction have a correspondence relationship;
transporting a plurality of before-treatment wafers from the wafer storage container, through the factory interface, the load-lock chamber and the wafer transfer chamber, to the reaction chamber in that order; and
transporting a plurality of after-treatment wafers from the reaction chamber, through the wafer transfer chamber, the load-lock chamber and the factory interface, to the wafer storage container in that order.

In the present invention, the carrier is configured with a counterbore depth in the circumferential direction of the top surface that is a depth that corresponds to the crystal orientation in the circumferential direction of the wafer, and
the counterbore depth at a crystal orientation at which the CVD film grows readily is greater than the counterbore depth at the crystal orientation at which the CVD film has difficulty growing.

More preferably, in the present invention, the counterbore depth is configured to change continuously and periodically in the circumferential direction.

More preferably, in the present invention, a pocket width of the carrier in the circumferential direction of the top surface is configured to be a pocket width that corresponds to the crystal orientation in the circumferential direction of the wafer, and
the pocket width at the crystal orientation at which the CVD film grows readily is less than the pocket width at the crystal orientation at which the CVD film has difficulty growing.

More preferably, in the present invention, the pocket width is configured to change continuously and periodically in the circumferential direction.

In addition, as another example in the present invention, when the carrier is rested on the top surface of the susceptor, the carrier works together with an outer circumferential projection of the susceptor to configure the top surface of the carrier,
the carrier and the susceptor are configured with a counterbore depth in the circumferential direction of the top surface that is a depth that corresponds to the crystal orientation in the circumferential direction of the wafer, and
the counterbore depth at a crystal orientation at which the CVD film grows readily is greater than the counterbore depth at the crystal orientation at which the CVD film has difficulty growing.

More preferably, in the present invention, the counterbore depth is configured to change continuously and periodically in the circumferential direction.

More preferably, in the present invention, when the carrier is rested on the top surface of the susceptor, the carrier works together with an outer circumferential projection of the susceptor to configure the top surface of the carrier,
a pocket width of the carrier and the susceptor in the circumferential direction of the top surface is configured to be a pocket width that corresponds to the crystal orientation in the circumferential direction of the wafer, and
the pocket width at the crystal orientation at which the CVD film grows readily is less than the pocket width at the crystal orientation at which the CVD film has difficulty growing.

More preferably, in the present invention, the pocket width is configured to change continuously and periodically in the circumferential direction.

### Effect of the Disclosure

According to the present invention, a structure or shape of a carrier, or of a carrier and a top surface of a susceptor, in a circumferential direction is configured to be a structure or shape that has a correspondence relationship to a crystal orientation in the circumferential direction of a wafer, and therefore variation in CVD film thickness resulting from the crystal orientation can be inhibited. As a result, thickness of a CVD film at a circumferential edge of the wafer can be made uniform.

### BRIEF DESCRIPTION OF THE DRAWINGS

FIG. 1 is a block diagram illustrating a vapor deposition device according to an embodiment of the present invention.

FIG. 2A is a plan view illustrating a carrier according to the embodiment of the present invention.

FIG. 2B is a cross-sectional view of the carrier, including a wafer and a reaction furnace susceptor.

FIG. 3A is a plan view illustrating a holder provided to a load-lock chamber.

FIG. 3B is a cross-sectional view of the holder including the wafer and the carrier.

FIGS. 4A through 4E illustrate plan views and cross-sectional views of a transfer protocol for the wafer and the carrier in the load-lock chamber.

FIGS. 5A through 5E illustrate plan views and cross-sectional views of a transfer protocol for the wafer and the carrier within a reaction chamber.

FIG. 6 is a plan view illustrating a crystal orientation of a silicon single crystal wafer having a (100) plane as the principal surface.

FIG. 7A is a cross-sectional view of relevant portions illustrating a first example of the carrier according to the present invention.

FIG. 7B is a plan view illustrating the carrier of FIG. 7A.

FIG. 7C is a diagram in which a top surface of the carrier of FIG. 7A is developed along a direction of an arrow in FIG. 7B.

FIG. 7D is a cross-sectional view of relevant portions illustrating another example of the first example of the carrier according to the present invention.

FIG. 8A is a cross-sectional view of relevant portions illustrating a second example of the carrier according to the present invention.

FIG. 8B is a plan view illustrating the carrier of FIG. 8A.

FIG. 8C is a diagram in which a pocket width of the carrier of FIG. 8A is developed along a direction of an arrow in FIG. 8B.

FIG. 8D is a cross-sectional view of relevant portions illustrating another example of the second example of the carrier according to the present invention.

FIG. 9 is a diagram (no. 1) illustrating a handling protocol for the wafer and the carrier in the vapor deposition device of the embodiment.

FIG. 10 is a diagram (no. 2) illustrating the handling protocol for the wafer and the carrier in the vapor deposition device of the embodiment.

FIG. 11 is a diagram (no. 3) illustrating the handling protocol for the wafer and the carrier in the vapor deposition device of the embodiment.

FIG. 12 is a diagram (no. 4) illustrating the handling protocol for the wafer and the carrier in the vapor deposition device of the embodiment.

### MODE FOR CARRYING OUT THE DISCLOSURE

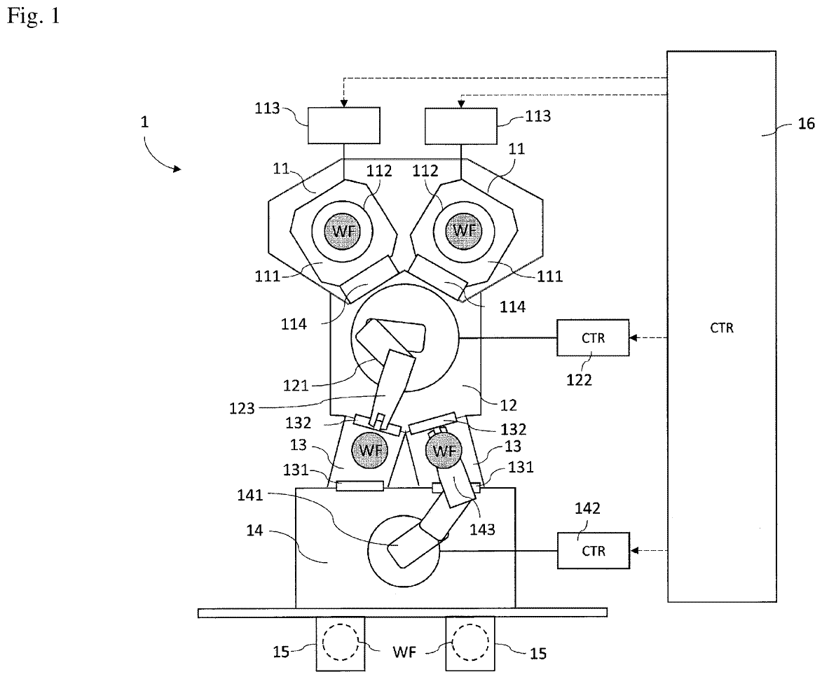

Hereafter, an embodiment of the present invention is described based on the drawings. FIG. 1 is a block diagram illustrating a vapor deposition device 1 according to the embodiment of the present invention. A main body of the vapor deposition device 1 shown in the center of the diagram is illustrated in a plan view. The vapor deposition device 1 of the present embodiment is what is known as a CVD device and is provided with a pair of reaction furnaces 11, 11; a wafer transfer chamber 12 in which is installed a first robot 121 that handles a wafer WF, such as a single crystal silicon wafer; a pair of load-lock chambers 13; a factory interface 14 in which is installed a second robot 141 that handles the wafer WF; and a load robot in which is installed a wafer storage container 15 (cassette case) in which a plurality of the wafers WF are stored.

The factory interface 14 is a zone configured to have the same air atmosphere as a clean room in which the wafer storage container 15 is mounted. The factory interface 14 is provided with the second robot 141, which extracts a before-treatment wafer WF that is stored in the wafer storage container 15 and deposits the wafer WF in the load-lock chamber 13, and also stores an after-treatment wafer WF transported to the load-lock chamber 13 in the wafer storage container 15. The second robot 141 is controlled by a second robot controller 142, and a second blade 143 mounted on a distal end of a robot hand displaces along a predetermined trajectory that has been taught in advance.

A first door 131 capable of opening and closing with an airtight seal is provided between the load-lock chamber 13 and the factory interface 14, while a second door 132 similarly capable of opening and closing with an airtight seal is provided between the load-lock chamber 13 and the wafer transfer chamber 12. In addition, the load-lock chamber 13 serves as a space where atmospheric gas exchange takes place between the wafer transfer chamber 12, which is configured to have an inert gas atmosphere, and the factory interface 14, which is configured to have an air atmosphere. Therefore, an exhaust device that evacuates an interior of the load lock chamber 13 to vacuum and a supply device that supplies inert gas to the load-lock chamber 13 are provided.

For example, when a before-treatment wafer WF is transported from the wafer storage container 15 to the wafer transfer chamber 12, in a state where the first door 131 on the factory interface 14 side is closed, the second door 132 on the wafer transfer chamber 12 side is closed, and the load-lock chamber 13 has an inert gas atmosphere, the wafer WF is extracted from the wafer storage container 15 using the second robot 141, the first door 131 on the factory interface 14 side is opened, and the wafer WF is transported to the load-lock chamber 13. Next, after the first door 131 on the factory interface 14 side is closed and the load-lock chamber 13 is restored to an inert gas atmosphere, the second door 132 on the wafer transfer chamber 12 side is opened and the wafer WF is transported to the wafer transfer chamber 12 using the first robot 121.

Conversely, when an after-treatment wafer WF is transported from the wafer transfer chamber 12 to the wafer storage container 15, in a state where the first door 131 on the factory interface 14 side is closed, the second door 132 on the wafer transfer chamber 12 side is closed, and the load-lock chamber 13 has an inert gas atmosphere, the second door 132 on the wafer transfer chamber 12 side is opened and the wafer WF in the wafer transfer chamber 12 is transported to the load-lock chamber 13 using the first robot 121. Next, after the second door 132 on the wafer transfer chamber 12 side is closed and the load-lock chamber 13 is restored to an inert gas atmosphere, the first door 131 on the factory interface 14 side is opened and the wafer WF is transported to the wafer storage container 15 using the second robot 141.

The wafer transfer chamber 12 is configured by a sealed chamber, connected on one side to the load-lock chamber 13 via the second door 132 that is capable of opening and closing and has an airtight seal, and connected on the other side via a gate valve 114 that is capable of opening and closing and has an airtight seal. The first robot 121, which transports the before-treatment wafer WF from the load-lock chamber 13 to the reaction chamber 111 and transports the after-treatment wafer WF from the reaction chamber 111 to the load-lock chamber 13, is installed on the wafer transfer chamber 12. The first robot 121 is controlled by a first robot controller 122, and a first blade 123 mounted on a distal end of a robot hand displaces along an operation trajectory that has been taught in advance.

An integrated controller 16 that integrates control of the entire vapor deposition device 1, the first robot controller 122, and the second robot controller 142 send and receive control signals amongst each other. In addition, when an operation command signal from the integrated controller 16 is sent to the first robot controller 122, the first robot controller 122 controls the operation of the first robot 121, and an operation result of the first robot 121 is sent from the first robot controller 122 to the integrated controller 16. Accordingly, the integrated controller 16 recognizes an operation status of the first robot 121. Similarly, when an operation command signal from the integrated controller 16 is sent to the second robot controller 142, the second robot controller 142 controls the operation of the second robot 141, and an operation result of the second robot 141 is sent from the second robot controller 142 to the integrated controller 16. Accordingly, the integrated controller 16 recognizes an operation status of the second robot 141.

Inert gas is supplied to the wafer transfer chamber 12 from an inert gas supply device not shown in the drawings, and gas in the wafer transfer chamber 12 is cleaned with a scrubber (scrubbing dust collector, precipitator) that is connected to an exhaust port, after which the gas is released outside the system. Although a detailed depiction is omitted, this type of scrubber can use a conventionally known pressurized water scrubber, for example.

The reaction furnace 11 is a device for growing an epitaxial film on a surface of the wafer WF using a CVD method, and includes a reaction chamber 111; a susceptor 112 on which the wafer WF is placed and rotated is provided inside the reaction chamber 111, and a gas supply device 113 is also provided that supplies hydrogen gas and raw material gas for growing a CVD film (when the CVD film is a silicon epitaxial film, the raw material gas may be silicon tetrachloride SiCl₄ or trichlorosilane SiHCl₃, for example) to the reaction chamber 111. In addition, although omitted from the drawings, a heat lamp for raising the temperature of the wafer WF to a predetermined temperature is provided around the circumference of the reaction chamber 111. Moreover, a gate valve 114 is provided between the reaction chamber 111 and the wafer transfer chamber 12, and airtightness with the wafer transfer chamber 12 of the reaction chamber 111 is ensured by closing the gate valve 114. Various controls, such as driving the susceptor 112 of the reaction furnace 11, supply and stoppage of gas by the gas supply device 113, turning the heat lamp on and off, and opening and closing the gate valve 114, are controlled by a command signal from the integrated controller 16. The vapor deposition device 1 shown in FIG. 1 depicts an example provided with a pair of reaction furnaces 11, 11, but the vapor deposition device 1 may have one reaction furnace 11 or three or more reaction furnaces.

A scrubber (scrubbing mist eliminator) having a similar configuration to that of the wafer transfer chamber 12 is provided to the reaction furnace 11. In other words, hydrogen gas or raw material gas supplied from the gas supply device 113 is cleaned by the scrubber connected to an exhaust port provided to the reaction chamber 111 and is then released outside the system. A conventionally known pressurized water scrubber, for example, can be used for this scrubber, as well.

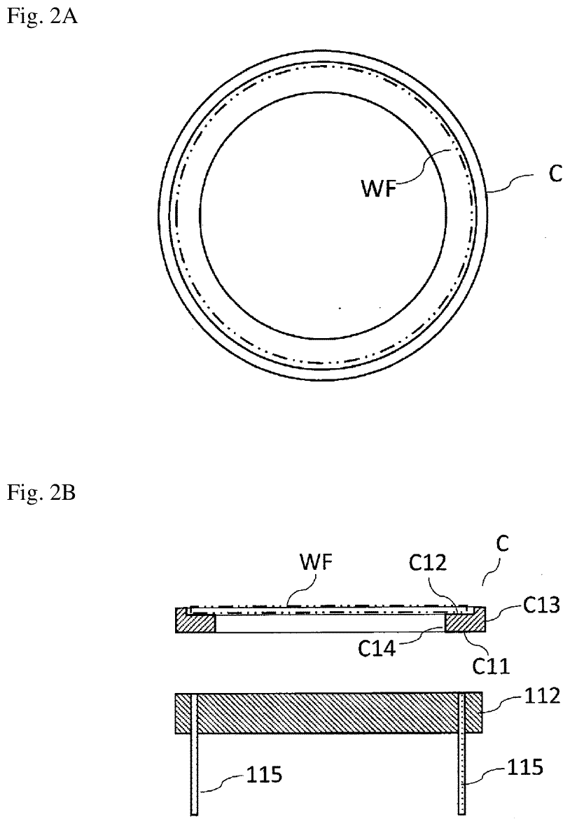

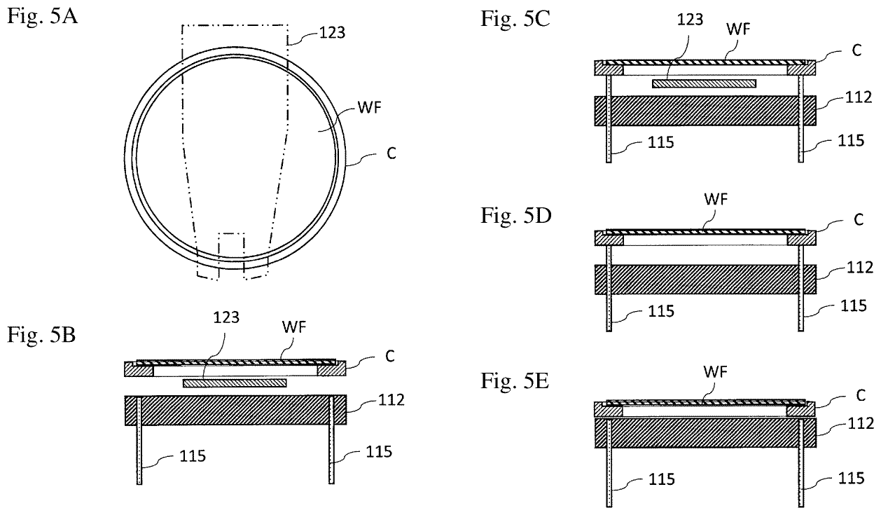

In the vapor deposition device 1 according to the present embodiment, the wafer WF is transported between the load-lock chamber 13 and the reaction chamber 111 using a ring-shaped carrier C that supports the entire outer circumferential edge of the wafer WF. FIG. 2A is a plan view of the carrier C, FIG. 2B is a cross-sectional view of the carrier C including the wafer WF and the susceptor 112 of the reaction furnace 11, and FIGS. 5A through 5E illustrate plan views and cross-sectional views of a transfer protocol for the wafer WF and the carrier C within the reaction chamber 111.

The carrier C according to the present embodiment is configured by a material such as SiC, for example; is formed in an endless ring shape; and includes a bottom surface C11 that rests on a top surface of the susceptor 112 shown in FIG. 2B, a top surface C12 that touches and supports the entire outer circumferential edge of a reverse face of the wafer WF, an outer circumferential wall surface C13, and an inner circumferential wall surface C14. In addition, when the wafer WF supported by the carrier C is transported into the reaction chamber 111, in a state where the carrier C rests on the first blade 123 of the first robot 121 as illustrated in the plan view of FIG. 5A, the wafer WF is transported to a top portion of the susceptor 112 as illustrated in FIG. 5B, the carrier C is temporarily lifted by three or more carrier lifting pins 115 provided to the susceptor 112 so as to be capable of displacing vertically as illustrated in FIG. 5C, and the first blade 123 is retracted as illustrated in FIG. 5D, after which the susceptor 112 is raised as illustrated in FIG. 5E, thereby placing the carrier C on the top surface of the susceptor 112.

Conversely, when treatment in the reaction chamber 111 has ended for the wafer WF and the wafer WF is withdrawn in a state mounted on the carrier C, the susceptor 112 is lowered from the state illustrated in FIG. 5E and supports the carrier C with only the carrier lifting pins 115 as illustrated in FIG. 5D, the first blade 123 is advanced between the carrier C and the susceptor 112 as illustrated in FIG. 5C, and then the three carrier lifting pins 115 are lowered to rest the carrier C on the first blade 123 as illustrated in FIG. 5B, and the hand of the first robot 121 is operated. In this way, the wafer WF for which treatment has ended can be withdrawn in a state mounted on the carrier C.

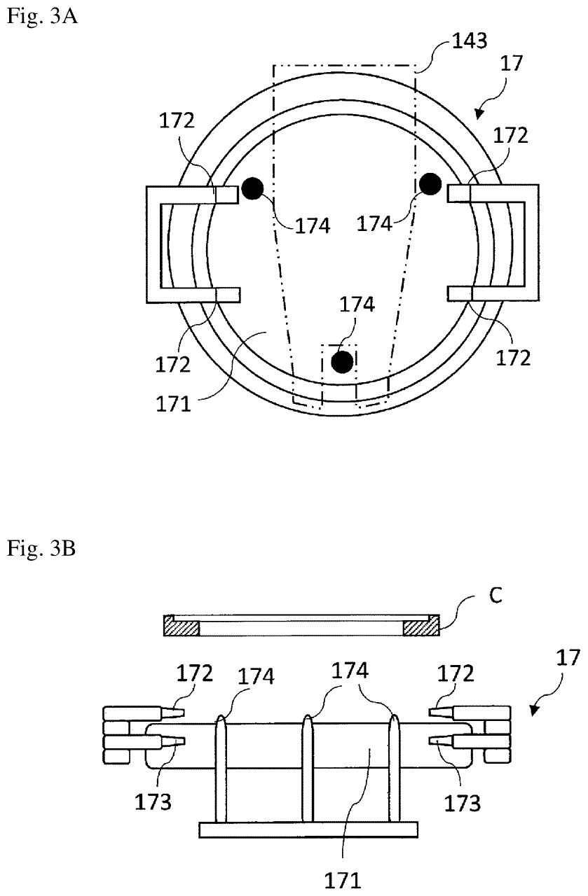

Also, in the vapor deposition device 1 according to the present embodiment, the carrier C is transported between processes running from the load-lock chamber 13 to the reaction chamber 111, and therefore in the load-lock chamber 13, the before-treatment wafer WF is placed on the carrier C and the after-treatment wafer WF is removed from the carrier C. Therefore, a holder 17 that supports the carrier C at two vertical levels is provided to the load-lock chamber 13. FIG. 3A is a plan view illustrating the holder 17 that is provided to the load-lock chamber 13, and FIG. 3B is a cross-sectional view of the holder 17 including the wafer WF. The holder 17 according to the present embodiment includes a fixed holder base 171; a first holder 172 and second holder 173 that support two carriers C at two vertical levels, and that are provided to the holder base 171 so as to be capable of lifting and lowering vertically; and three wafer lifting pins 174 that are provided to the holder base 171 so as to be capable of lifting and lowering vertically.

The first holder 172 and the second holder 173 (in the plan view of FIG. 3A, the second holder 173 is obscured by the first holder 172 and therefore only the first holder 172 is depicted) have projections for supporting the carrier C at four points, and one carrier C is placed on the first holder 172 and another carrier C is placed on the second holder 173. The carrier C that rests on the second holder 173 is inserted into a gap between the first holder 172 and the second holder 173.

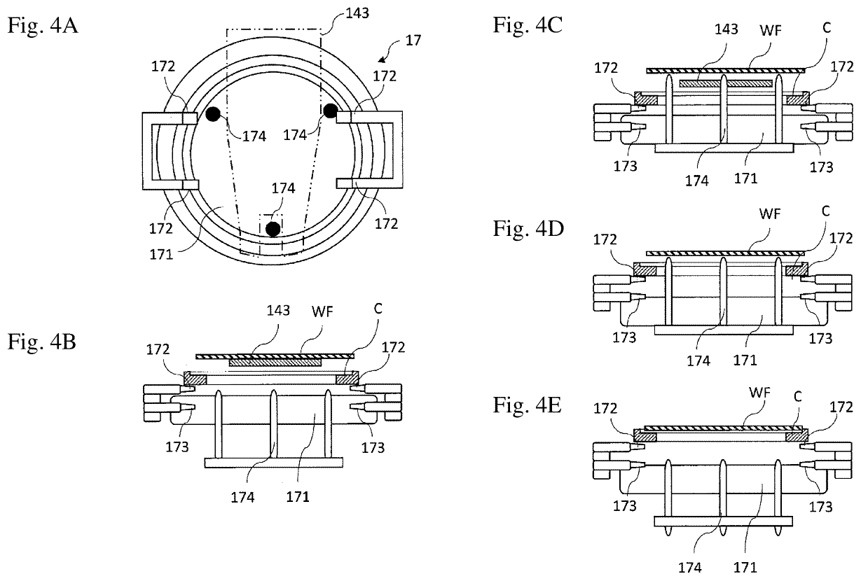

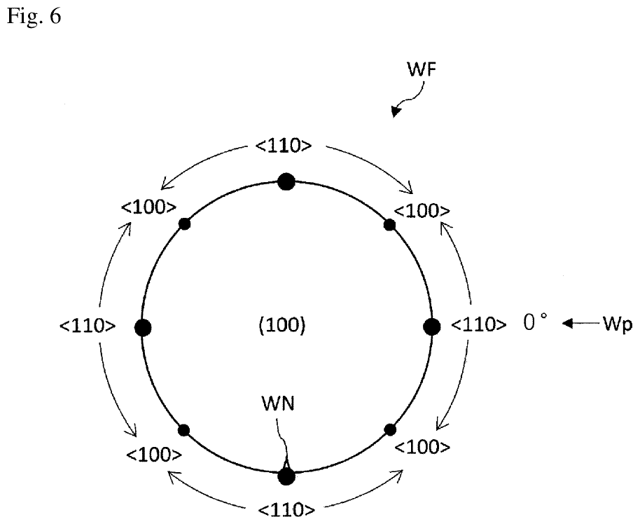

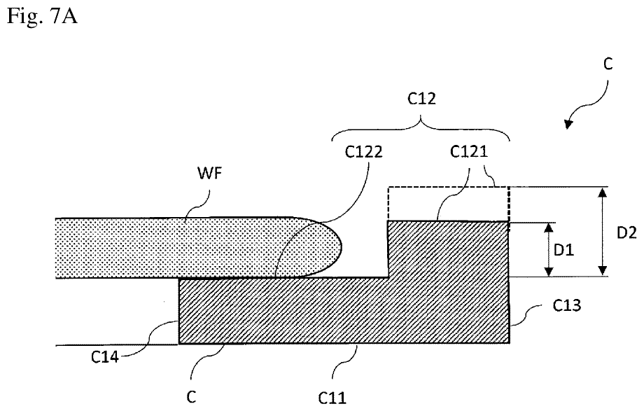

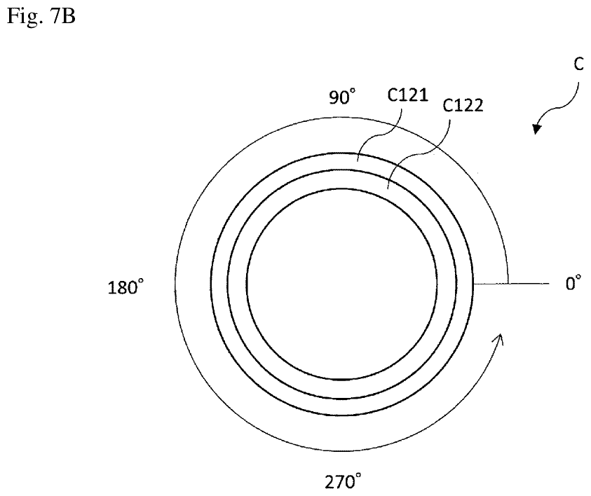

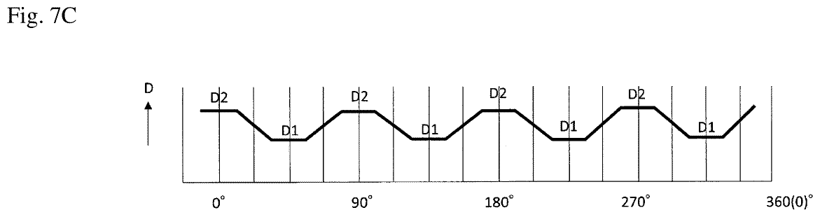

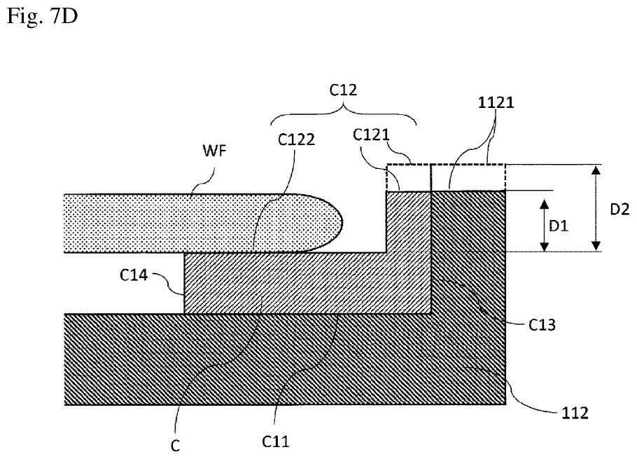

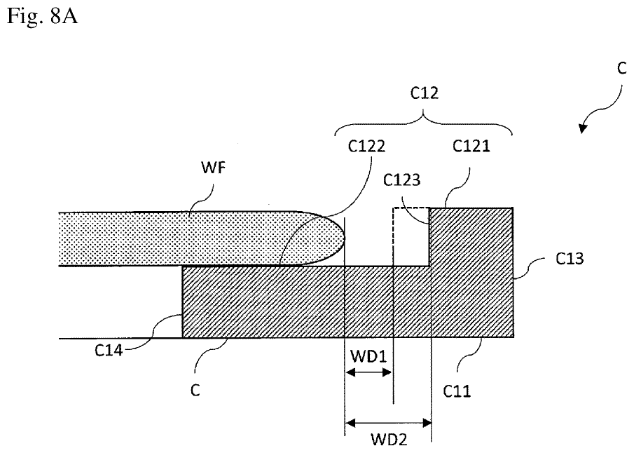

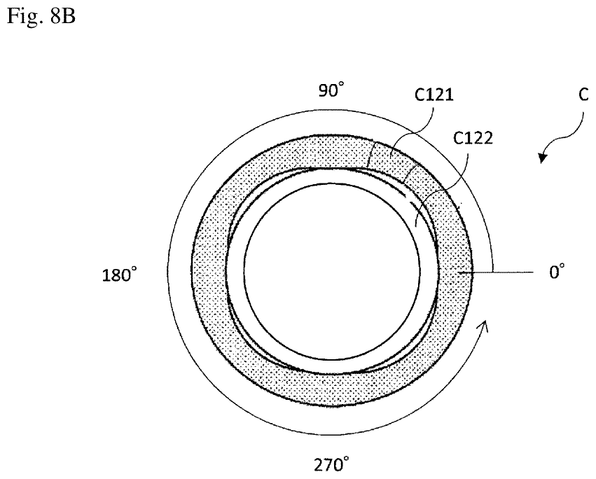

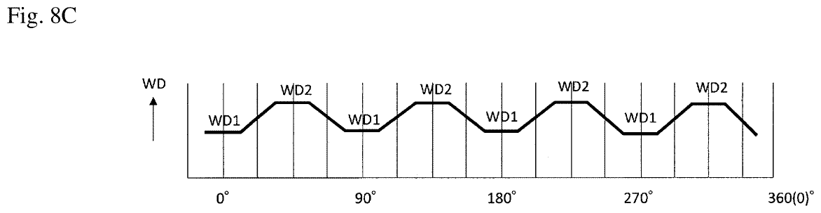

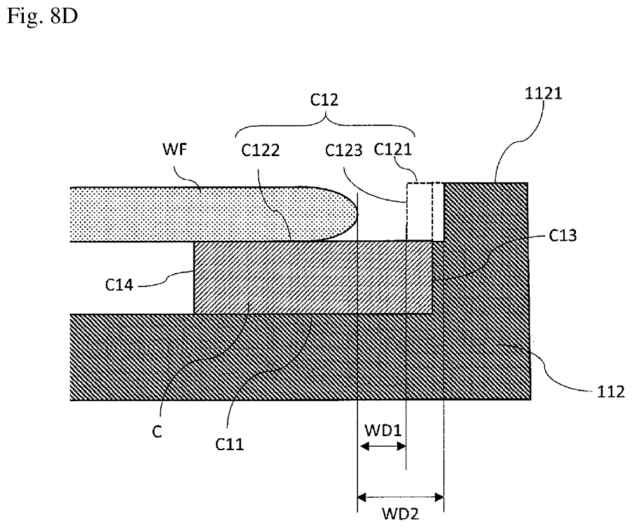

FIGS. 4A through 4E illustrate plan views and cross-sectional views of a transfer protocol for the wafer WF and carrier C in the load-lock chamber 13 and depicts a protocol in which a before-treatment wafer WF rests on the carrier C in a state where the carrier C is supported by the first holder 172, as illustrated in FIG. 4B. In other words, the second robot 141 that is provided to the factory interface 14 loads one wafer WF that is stored in the wafer storage container 15 onto the second blade 143 and transports the wafer WF via the first door 131 of the load-lock chamber 13 to a top portion of the holder 17, as illustrated in FIG. 4B. Next, as illustrated in FIG. 4C, the three wafer lifting pins 174 are raised relative to the holder base 171 and temporarily hold up the wafer WF, and the second blade 143 is retracted as illustrated in FIG. 4D. The three wafer lifting pins 174 are provided in positions that do not interfere with the second blade 143, as illustrated in the plan view of FIG. 4A. Next, as illustrated in FIGS. 4D and 4E, the three wafer lifting pins 174 are lowered and the first holder 172 and the second holder 173 are raised, whereby the wafer WF is placed on the carrier C. In this case, so that a positional relationship between the second blade 143 and a circumferential direction position of the wafer WF (specifically a position of a notch WN (see FIG. 6)) fulfills a predetermined relationship, whether the wafer WF is stored in the wafer storage vessel 15 with the direction of the wafer WF aligned ahead of time or whether the second robot 141 places the wafer WF on the second blade 143 with the direction of the wafer WF aligned, the second robot 141 loads the wafer WF such that, ultimately, a relationship between a circumferential direction position on the carrier C and a circumferential direction position on the wafer WF fulfill a relationship as in FIG. 7C or FIG. 8C, described below.

Conversely, when the after-treatment wafer WF transported to the load-lock chamber 13 in a state resting on the carrier C is transported to the wafer storage container 15, as illustrated in FIG. 4D, the three wafer lifting pins 174 are raised and the first holder 172 and the second holder 173 are lowered from the state illustrated in FIG. 4E, the wafer WF is supported by only the wafer lifting pins 174, and the second blade 143 is advanced between the carrier C and the wafer WF as illustrated in FIG. 4C, after which the three wafer lifting pins 174 are lowered to load the wafer WF on the second blade 143 as illustrated in FIG. 4B, and the hand of the second robot 141 is operated. In this way, the wafer WF for which treatment has ended can be taken out of the carrier C and into the wafer storage container 15. In the state illustrated in FIG. 4E, the wafer WF for which treatment has ended is transported to the first holder 172 in a state resting on the carrier C, but the wafer WF can be taken out of the carrier C and into the wafer storage container 15 with a similar protocol when the wafer WF is transported to the second holder 173, as well.

In particular, the carrier C according to the present embodiment has a structure or shape that corresponds to a crystal orientation of the wafer WF (silicon single crystal wafer, for example) that is a substrate in the CVD process, and this structure or shape makes the CVD film thickness on the circumferential edge of the wafer uniform. FIG. 6 is a plan view illustrating a crystal orientation of the wafer WF (strictly speaking, a silicon single crystal wafer) having a (100) plane as the principal surface. A notch WN indicating the crystal orientation is formed in one location on the outer circumferential edge of the wafer WF in a step of slicing the wafer from a silicon single crystal ingot. The crystal orientation in the present specification uses angles up to 360° counterclockwise with an origin point Wp as a reference point for 0°, as illustrated in the plan view of the wafer WF illustrated in FIG. 6. As illustrated in FIG. 6, the crystal orientation in the outer circumferential direction of the wafer WF having a (100) plane as the principal surface repeats crystal orientations that are replicated in mirror fashion every 45°, where 0° is <110>, 45° is <100>, and 90° is <110>, and moreover the crystal orientation is repeated every period of 90°. The interval from 0° to 45° is <230>, <120>, and <130>. In addition, a film thickness distribution of the outer circumferential edge of the wafer WF is dependent on the crystal orientation; the film is thicker in the vicinity of) 0° (360°, 90°, 180°, and 270°, and is thinner in the vicinity of 45°, 135°, 230°, and 315°. In other words, the film is relatively thick in ranges where the crystal orientation is in the <110> direction and is relatively thin in ranges where the crystal orientation is in the <100> direction, and the film thickness between these ranges changes continuously.

Therefore, the carrier C according to the present embodiment is configured with a structure or shape as described below. FIG. 7A is a cross-sectional view of relevant portions illustrating a first example of the carrier C, FIG. 7B is a plan view illustrating the first example of the carrier C, and FIG. 7C is a diagram in which the top surface C12 of the first example of the carrier C is developed along a direction of an arrow in FIG. 7B. The carrier C according to the first example includes the bottom surface C11 that rests on the top surface of the susceptor 112, the top surface C12 that touches and supports the entire outer circumferential edge of the reverse face of the wafer WF, the outer circumferential wall surface C13, and the inner circumferential wall surface C14, and the top surface C12 further includes a top surface C121 which is connected to the outer circumferential wall surface C13 and a top surface C122 which is connected to the inner circumferential wall surface C14. Also, the entire outer circumferential edge of the wafer WF touches and rests on the top surface C122.

In this example, when the vertical direction height from the top surface C121 to a position where the outer circumferential edge of the wafer WF touches the top surface C122 is defined as a counterbore depth D, the carrier C according to the present embodiment has a shape with a relatively large counterbore depth D2 in the vicinity of 0° (360°), 90°, 180°, and 270°, and a relatively small counterbore depth D1 in the vicinity of 45°, 135°, 230°, and 315°, as illustrated in FIG. 7C, and in which the height of the top surface C121 changes periodically in the circumferential direction such that the intervening counterbore depths change continuously between D1 and D2.

In the cross-sectional view of FIG. 7A, at a portion where the counterbore depth is the large D2, a portion of reaction gas flow flowing in a horizontal direction is blocked by the top surface C121 that is formed to be relatively high, which leads to stagnation of the reaction gas flow on the perimeter of the outer circumferential edge of the wafer WF and reaction gas flow volume is slightly reduced. In contrast, in the cross-sectional view of FIG. 7A, at a portion where the counterbore depth is the small D1, the reaction gas flow flowing in the horizontal direction flows without a portion being obstructed by the top surface C121 that is formed to be relatively low, and therefore reaction gas having a target reaction gas flow volume flows to include the outer circumferential edge of the wafer WF. Therefore, by changing the counterbore depth along the circumferential direction as in the development diagram of FIG. 7C, the thickness of the CVD film is relatively thin in the vicinity of 0° (360°), 90°, 180°, and 270°, and is relatively thick in the vicinity of 45°, 135°, 230°, and 315°. However, as described above, in a wafer having a (100) plane as the principal surface, the film is relatively thick in ranges where the crystal orientation is in a <110> direction and is relatively thin in ranges where the crystal orientation is in a <100> direction, and the film thickness between these ranges changes continuously; therefore, by setting the counterbore depth of the carrier C as in the first example, periodic variation in film thickness resulting from the crystal orientation can be eliminated.

FIG. 7D is a cross-sectional view of relevant portions illustrating another example of the first example of the carrier C according to the present invention. An outer diameter of the carrier C illustrated in FIG. 7D is smaller than the outer diameter of the carrier C illustrated in FIG. 7A, and therefore when resting on the top surface of the susceptor 112, the carrier C works together with an outer circumferential projection 1121 of the susceptor 112 to configure the top surface C121. In this example, when the vertical direction height from a position where the outer circumferential edge of the wafer WF touches the top surface C122 to the top surface C121 of the carrier C and the top surface of the outer circumferential projection 1121 of the susceptor 112 is defined as the counterbore depth D, the carrier C according to the present embodiment has a shape with a relatively large counterbore depth D2 in the vicinity of 0° (360°), 90°, 180°, and 270°, and a relatively small counterbore depth D1 in the vicinity of 45°, 135°, 230°, and 315°, as illustrated in FIG. 7C, and in which the height of the top surface C121 of the carrier C and the top surface of the outer peripheral projection 1121 of the susceptor 112 changes periodically in the circumferential direction such that the intervening counterbore depths change continuously between D1 and D2.

Aside from the first example described above, when the carrier C according to the present embodiment has a structure or shape that corresponds to the crystal orientation of the wafer WF that is the substrate in the CVD process, the carrier C can have the structure or shape of a second example. FIG. 8A is a cross-sectional view of relevant portions illustrating the second example of the carrier C according to the present invention, FIG. 8B is a plan view illustrating the carrier C, and FIG. 8C is a diagram in which a pocket width of the carrier C is developed along a direction of an arrow in FIG. 8B.

The carrier C according to the second example includes the bottom surface C11 that rests on the top surface of the susceptor 112, the top surface C12 that touches and supports the entire outer circumferential edge of the reverse face of the wafer WF, the outer circumferential wall surface C13, and the inner circumferential wall surface C14, and the top surface C12 further includes the top surface C121 which is connected to the outer circumferential wall surface C13 and the top surface C122 which is connected to the inner peripheral wall surface C14. Also, the entire outer circumferential edge of the wafer WF touches and rests on the top surface C122.

In this example, when the horizontal direction distance from the outer circumferential edge of the wafer WF to an interface C123 (vertical wall surface) between the top surface C121 and the top surface C122 is defined as a pocket width WD, the carrier C according to the present embodiment has a shape with a relatively small pocket width WD1 in the vicinity of 0° (360°), 90°, 180°, and 270°, and a relatively large pocket width WD2 in the vicinity of 45°, 135°, 230°, and 315°, as illustrated in FIG. 8C, and in which the position of the interface C123 changes periodically in the circumferential direction such that the intervening pocket widths change continuously between WD1 and WD2.

In the cross-sectional view of FIG. 8A, a portion of the reaction gas flow flowing in the horizontal direction is blocked by the top surface C121, which leads to stagnation of the reaction gas flow on the perimeter of the outer circumferential edge of the wafer WF and the reaction gas flow volume is slightly reduced. In this example, at a portion with the small pocket width WD1, because the pocket width is small, the stagnation of the reaction gas flow halts at the top portion of the outer circumferential edge of the wafer WF, and therefore the reaction gas flow volume on the outer circumferential edge of the wafer WF is slightly reduced. In contrast, at a portion with the large pocket width WD2, the stagnation of the reaction gas flow shifts into a portion with a broad pocket width, and therefore a target reaction gas flow volume flows to include the outer circumferential edge of the wafer WF. Therefore, by changing the pocket width along the circumferential direction as in the development diagram of FIG. 8C, the thickness of the CVD film becomes relatively thin in the vicinity of) 0° (360°, 90°, 180°, and 270°, and becomes relatively thick in the vicinity of 45°, 135°, 230°, and 315°. However, as noted above, in a wafer having a (100) plane as the principal surface, the film is relatively thick in ranges where the crystal orientation is in the <110> direction and is relatively thin in ranges where the crystal orientation is in the <100> direction, and the film thickness between these ranges changes continuously; therefore, by defining the pocket width of the carrier C as in the second example, periodic variation in the film thickness resulting from the crystal orientation can be eliminated.

FIG. 8D is a cross-sectional view of relevant portions illustrating another example of the second example of the carrier C according to the present invention. An outer diameter of the carrier C illustrated in FIG. 8D is smaller than the outer diameter of the carrier C illustrated in FIG. 8A, and therefore when resting on the top surface of the susceptor 112, the carrier C works together with an outer circumferential projection 1121 of the susceptor 112 to configure the top surface C121. In this example, when the horizontal direction distance from the outer circumferential edge of the wafer WF to the interface C123 (vertical wall surface) between the top surface C121 and the top surface C122 is defined as the pocket width WD, the carrier C according to the present embodiment has a shape with a relatively small pocket width WD1 in the vicinity of) 0° (360°, 90°, 180°, and 270°, and a relatively large pocket width WD2 in the vicinity of 45°, 135°, 230°, and 315°, as illustrated in FIG. 8C, and in which the position of the interface C123 changes periodically in the circumferential direction such that the intervening pocket widths change continuously between WD1 and WD2. The portions where the pocket width is relatively large lack projecting portions on the outer circumference of the carrier C, and also the inner wall of the outer circumferential projection 1121 of the susceptor 112 is configured in a recessed shape.

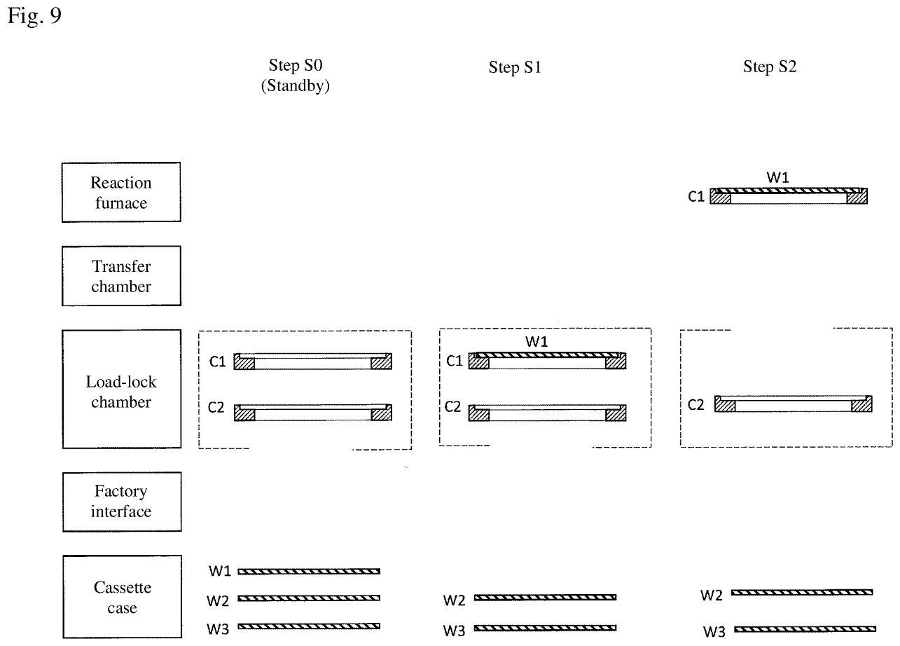

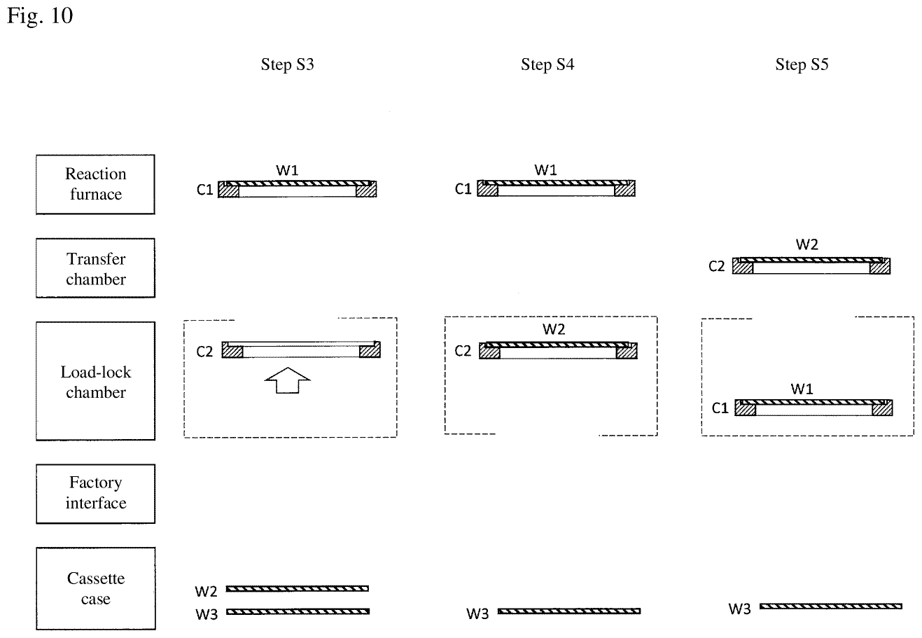

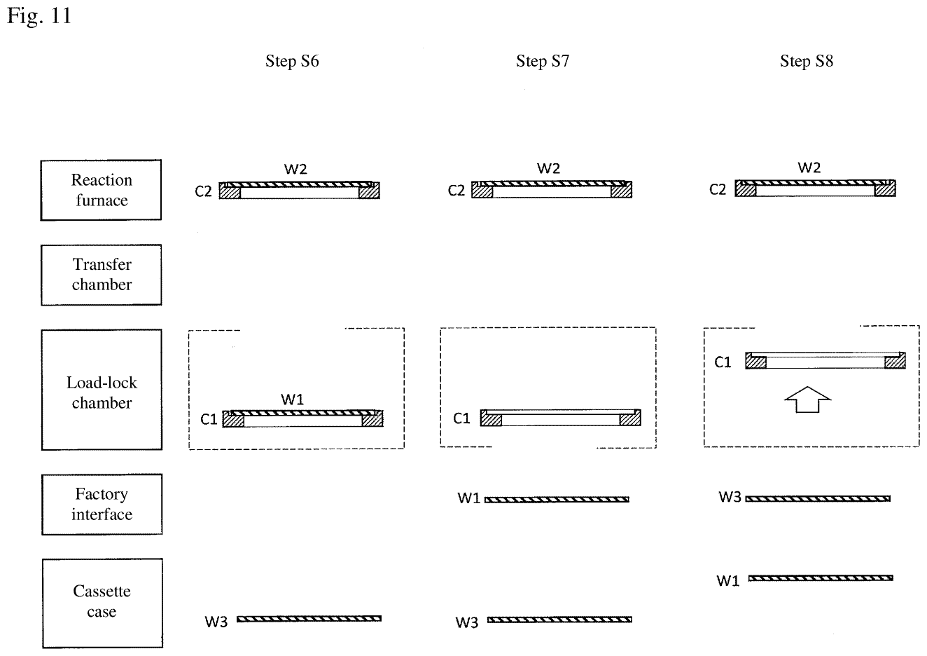

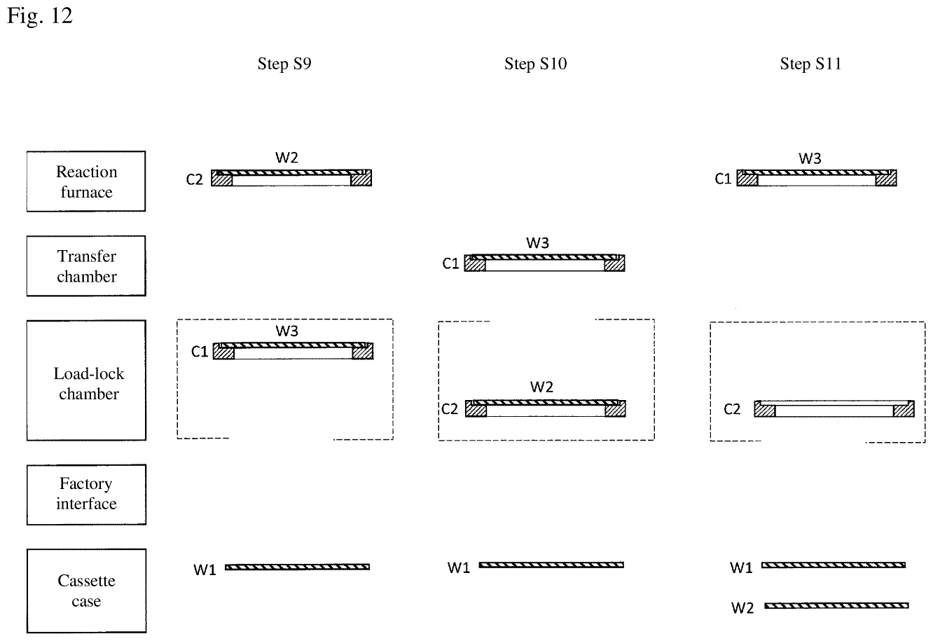

Next a protocol is described for handling the carrier C and the wafer WF prior to creating the epitaxial film (hereafter referred to simply as “before-treatment”) and after creating the epitaxial film (hereafter referred to simply as “after-treatment”) in the vapor deposition device 1 according to the present embodiment. FIGS. 9 to 12 are schematic views illustrating a handling protocol for a wafer and a carrier in the vapor deposition device of the present embodiment and correspond to the wafer storage container 15 on one side of the device, the load-lock chamber 13, and the reaction furnace 11 in FIG. 1; a plurality of wafers W1, W2, W3, . . . (for example, a total of 25 wafers) are stored in the wafer storage container 15 and treatment is initiated in that order.

Step S0 in FIG. 9 shows a standby state from which treatment using the vapor deposition device 1 is to begin, and has the plurality of wafers W1, W2, W3, . . . (for example, a total of 25 wafers) stored in the wafer storage container 15, has an empty carrier C1 supported by the first holder 172 of the load-lock chamber 13, has an empty carrier C2 supported by the second holder 173, and has an inert gas atmosphere in the load-lock chamber 13.

In the next step (step S1), the second robot 141 loads the wafer W1 that is stored in the wafer storage container 15 onto the second blade 143 and transfers the wafer W1 through the first door 131 of the load-lock chamber 13 to the carrier C1 that is supported by the first holder 172. The protocol for this transfer was described with reference to FIGS. 4A through 4E.

In the next step (step S2), the first door 131 of the load-lock chamber 13 is closed and, in a state where the second door 132 is also closed, the interior of the load-lock chamber 13 undergoes gas exchange to the inert gas atmosphere. Then, the second door 132 is opened, the carrier C1 is loaded onto the first blade 123 of the first robot 121, the gate valve 114 of the reaction furnace 11 is opened, and the carrier C1 on which the wafer W1 is mounted is transferred through the gate valve 114 to the susceptor 112. The protocol for this transfer was described with reference to FIGS. 4A through 4E. In steps S2 to S4, the CVD film creation process is performed on the wafer W1 in the reaction furnace 11.

In other words, the carrier C1 on which the before-treatment wafer W1 is mounted is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W1 in the reaction chamber 111 is heated to a predetermined temperature by the heat lamp and pretreatment such as etching or heat treatment is performed as necessary, after which the gas supply device 113 supplies raw material gas while controlling the flow volume and/or supply time. This creates a CVD film on the surface of the wafer W1. Once the CVD film is formed, the gas supply device 113 once again supplies the reaction chamber 111 with hydrogen gas and the reaction chamber undergoes gas exchange to a hydrogen gas atmosphere, after which the protocol stands by for a predetermined amount of time.

While the reaction furnace 11 is treating the wafer W1 in steps S2 to S4, the second robot 141 extracts the next wafer (W2) from the wafer storage container 15 and prepares for the next treatment. Prior to this, in step S3 in the present embodiment, the second door 132 of the load-lock chamber 13 is closed, and in a state where the first door 131 is also closed, the interior of the load-lock chamber 13 undergoes gas exchange to an inert gas atmosphere. Then, the second door 132 is opened, the carrier C2 supported by the second holder 173 is transferred to the first holder 172 by the first robot 121, and the second door 132 is closed. Subsequently, in step S4, the second robot 141 loads the wafer W2 that was stored in the wafer storage container 15 onto the second blade 143, the first door 131 is opened, and the wafer W2 is transferred to the carrier C2 that is supported by the first holder 172 of the load-lock chamber 13.

In this way, in the present embodiment, step S3 is added and the before-treatment wafer WF that was stored in the wafer storage container 15 is mounted on the first holder 172, which is the topmost-level holder of the holder 17 of the load-lock chamber 13. This is for the following reasons. Specifically, as illustrated in step S2, when the empty carrier C2 on which the next wafer W2 is to be mounted is supported by the second holder 173, once the wafer W2 is mounted on the carrier C2, there is a possibility that the after-treatment wafer W1 may be transferred to the first holder 172. The carrier C of the vapor deposition device 1 according to the present embodiment is transported to the reaction chamber 111, and therefore the carrier C is a factor in particle production, and when the carrier C1 is held above the before-treatment wafer W2, dust may fall on the before-treatment wafer W2. Therefore, step S3 is added and the empty carrier C2 is transferred to the first holder 172 so that the before-treatment wafer WF is mounted on the topmost-level holder (first holder 172) of the holder 17 of the load-lock chamber 13.

In step S5, the first door 131 of the load-lock chamber 13 is closed and, in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C1 on which the after-treatment wafer W1 is mounted, the carrier C1 is withdrawn from the reaction chamber 111, and the gate valve 114 is closed, after which the second door 132 is opened and the carrier C1 is transferred to the second holder 173 of the load-lock chamber 13. Subsequently, the carrier C2 supported by the first holder 172 is loaded onto the first blade 123 of the first robot 121 and, as illustrated in step S6, the gate valve 114 is opened and the carrier C2 on which the before-treatment wafer W2 is mounted is transferred through the wafer transfer chamber 12 to the susceptor 112 of the reaction furnace 11.

In steps S6 to S9, the CVD film creation process is performed on the wafer W2 in the reaction furnace 11. In other words, the carrier C2 on which the before-treatment wafer W2 is mounted is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W2 in the reaction chamber 111 is heated to a predetermined temperature by the heat lamp and pretreatment such as etching or heat treatment is performed as necessary, after which the gas supply device 113 supplies raw material gas while controlling the flow volume and/or supply time. This creates a CVD film on the surface of the wafer W2. Once the CVD film is formed, the gas supply device 113 once again supplies the reaction chamber 111 with hydrogen gas and the reaction chamber 111 undergoes gas exchange to a hydrogen gas atmosphere, after which the protocol stands by for a predetermined amount of time.

In this way, while the reaction furnace 11 is treating the wafer W2 in steps S6 to S9, the second robot 141 stores the after-treatment wafer W1 in the wafer storage container 15 and also extracts the next wafer (W3) from the wafer storage container 15 and prepares for the next treatment. In other words, in step S7, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the after-treatment wafer W1 onto the second blade 143 from the carrier C1 supported by the second holder 173 and, as illustrated in step S8, the after-treatment wafer W1 is stored in the wafer storage container 15. Subsequently, similarly to step S3 described above, in step S8, the first door 131 of the load-lock chamber 13 is closed, and in a state where the second door 132 is also closed, the interior of the load-lock chamber 13 undergoes gas exchange to an inert gas atmosphere. Then, the carrier C2 supported by the second holder 173 is transferred to the first holder 172 by the first robot 121.

Subsequently, in step S9, the second door 132 of the load-lock chamber 13 is closed, and in a state where the first door 131 is also closed, the interior of the load-lock chamber 13 undergoes gas exchange to an inert gas atmosphere. Then, the second robot 141 loads the wafer W3 that was stored in the wafer storage container 15 onto the second blade 143 and, as illustrated in step S9, the first door 131 is opened and the wafer W3 is transferred to the carrier C1 that is supported by the first holder 172 of the load-lock chamber 13.

In step S10, similarly to step S5 described above, the first door 131 of the load-lock chamber 13 is closed, and in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C2 on which the after-treatment wafer W2 is mounted, and the gate valve 114 is closed, after which the second door 132 is opened and the carrier C2 is transferred from the reaction chamber 111 to the second holder 173 of the load-lock chamber 13. Subsequently, the carrier C1 supported by the first holder 172 is loaded onto the first blade 123 of the first robot 121 and, as illustrated in step S11, the carrier C1 on which the before-treatment wafer W3 is mounted is transferred through the wafer transfer chamber 12 to the susceptor 112 of the reaction furnace 11.

In step S10, similarly to step S7 described above, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the post-treatment wafer W2 onto the second blade 143 from the carrier C2 that is supported on the second holder 173 and, as illustrated in step S11, the post-treatment wafer W2 is stored in the wafer storage container 15. Thereafter, the above steps are repeated until treatment for all of the before-treatment wafers WF stored in the wafer storage container 15 ends.

As described above, the vapor deposition device 1 according to the present embodiment provides a structure or shape of the carrier C on which the wafer WF is mounted and transported to the reaction chamber 111, and specifically a structure or shape where the pocket width WD or the counterbore depth D along the circumferential direction has a correspondence relationship to the crystal orientation in the circumferential direction of the wafer WF, and moreover, when the second robot 141 mounts the before-treatment wafer WF on the carrier C, the wafer WF is mounted with adjustment in a direction in which the crystal orientation in the circumferential direction of the before-treatment wafer WF and the structure or shape in the circumferential direction have a correspondence relationship, and therefore periodic variation in the film thickness resulting from the crystal orientation can be eliminated.

In addition, in the vapor deposition device 1 according to the present embodiment, while treatment is ongoing in the reaction furnace 11, the next before-treatment wafer WF is extracted from the wafer storage container 15 and prepared, the after-treatment wafer WF is stored in the wafer storage container 15, and the like, and so the amount of time consumed simply in transport is drastically reduced. In such a case, when a number of standby carriers C in the load lock chamber 13 is set to two or more, as with the holder 17 in the present embodiment, a degree of freedom in shortening the amount of time consumed simply in transport can be substantially increased. Furthermore, when the space dedicated to the load-lock chamber 13 is considered, aligning the plurality of carriers C in multiple vertical levels reduces the space dedicated to the vapor deposition device 1 overall as compared to aligning the plurality of carriers C left-to-right. But, when the plurality of carriers C are aligned in multiple vertical levels, the carrier C may be held above a before-treatment wafer WF and dust may fall on the before-treatment wafer WF. However, in the vapor deposition device 1 according to the present embodiment, steps S3 and S8 are added and the empty carrier C2 is transferred to the first holder 172 so that the before-treatment wafer WF is mounted on the topmost-level holder (first holder 172) of the holder 17 of the load-lock chamber 13, and therefore the before-treatment wafer WF is mounted on the topmost-level carrier C. As a result, particles originating from the carrier C can be inhibited from adhering to the wafer WF and LPD quality can be improved.

### DESCRIPTION OF REFERENCE NUMERALS

1 . . . Vapor deposition device
11 . . . Reaction furnace
111 . . . Reaction chamber
112 . . . Susceptor
113 . . . Gas supply device
114 . . . Gate valve
115 . . . Carrier lifting pin
12 . . . Wafer transfer chamber
121 . . . First robot
122 . . . First robot controller
123 . . . First blade
13 . . . Load-lock chamber
131 . . . First door
132 . . . Second door
14 . . . Factory interface
141 . . . Second robot
142 . . . Second robot controller
143 . . . Second blade
15 . . . Wafer storage container
16 . . . Integrated controller
17 . . . Holder
171 . . . Holder base
172 . . . First holder
173 . . . Second holder
174 . . . Wafer lifting pin
C . . . Carrier
C11 . . . Bottom surface
C12 . . . Top surface
C13 . . . Outer circumferential wall surface
C14 . . . Inner circumferential wall surface
WF . . . Wafer

1. A method for manufacturing epitaxial wafers comprising:
preparing a vapor deposition device which is provided with a ring-shaped carrier that supports an outer edge of a wafer, and which uses a plurality of the carriers,
wherein the vapor deposition device comprises a factory interface, a load-lock chamber, a wafer transfer chamber and a reaction chamber,
the load-lock chamber communicates with the factory interface via a first door and also communicates with the wafer transfer chamber via a second door,
the wafer transfer chamber communicates, via a gate valve, with the reaction chamber in which a CVD film is formed on the wafer,
the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber,
the factory interface is provided with a second robot that extracts the before-treatment wafer from a wafer storage container and mounts the wafer on a carrier standing by in the load-lock chamber, and also stores in the wafer storage container an after-treatment wafer mounted on the carrier that has been transported to the load-lock chamber,
the load-lock chamber is provided with a holder that supports the carrier,
the reaction chamber is provided with a susceptor that supports the carrier,
the carrier is formed in an endless ring shape having a bottom surface that rests on a top surface of the susceptor, a top surface touching and supporting an outer edge of a reverse face of the wafer, an outer circumferential wall surface, and an inner circumferential wall surface, and
the carrier, or the carrier and the susceptor, are configured with a structure or shape in a circumferential direction of the top surface that has a correspondence relationship to a crystal orientation in the circumferential direction of the wafer;
mounting the before-treatment wafer on the carrier such that the crystal orientation in the circumferential direction of the before-treatment wafer and the structure or shape of the carrier, or of the carrier and the susceptor, in the circumferential direction have a correspondence relationship;
transporting a plurality of before-treatment wafers from the wafer storage container, through the factory interface, the load-lock chamber and the wafer transfer chamber, to the reaction chamber in that order; and
transporting a plurality of after-treatment wafers from the reaction chamber, through the wafer transfer chamber, the load-lock chamber and the factory interface, to the wafer storage container in that order.

2. The method according to claim 1, wherein the carrier is configured with a counterbore depth in the circumferential direction of the top surface that is a depth that corresponds to the crystal orientation in the circumferential direction of the wafer, and
the counterbore depth at a crystal orientation at which the CVD film grows readily is greater than the counterbore depth at the crystal orientation at which the CVD film has difficulty growing.

3. The method according to claim 2, wherein the counterbore depth is configured to change continuously and periodically in the circumferential direction.

4. The method according to claim 1, wherein a pocket width of the carrier in the circumferential direction of the top surface is configured to be a pocket width that corresponds to the crystal orientation in the circumferential direction of the wafer, and
the pocket width at the crystal orientation at which the CVD film grows readily is less than the pocket width at the crystal orientation at which the CVD film has difficulty growing.

5. The method according to claim 4, wherein the pocket width is configured to change continuously and periodically in the circumferential direction.

6. The method according to claim 1, wherein when the carrier is rested on the top surface of the susceptor, the carrier works together with an outer circumferential projection of the susceptor to configure the top surface of the carrier,
the carrier and the susceptor are configured with a counterbore depth in the circumferential direction of the top surface that is a depth that corresponds to the crystal orientation in the circumferential direction of the wafer, and
the counterbore depth at a crystal orientation at which the CVD film grows readily is greater than the counterbore depth at the crystal orientation at which the CVD film has difficulty growing.

7. The method according to claim 6, wherein the counterbore depth is configured to change continuously and periodically in the circumferential direction.

8. The method according to claim 1, wherein when the carrier is rested on the top surface of the susceptor, the carrier works together with an outer circumferential projection of the susceptor to configure the top surface of the carrier,
a pocket width of the carrier and the susceptor in the circumferential direction of the top surface is configured to be a pocket width that corresponds to the crystal orientation in the circumferential direction of the wafer, and
the pocket width at the crystal orientation at which the CVD film grows readily is less than the pocket width at the crystal orientation at which the CVD film has difficulty growing.

9. The method according to claim 8, wherein the pocket width is configured to change continuously and periodically in the circumferential direction.
